(19) United States
(12) Patent Application Publication
(10) Pub. No.: US 2026/0214958 A1
(43) Pub. Date: Jul. 23, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Kazuki MIZUTANI, Chuo Tokyo (JP); Ryohei NEGA, Yokohama Kanagawa (JP)

(21) Appl. No.: 19/370,649

(22) Filed: Oct. 27, 2025

(30) Foreign Application Priority Data
Jan. 17, 2025 (JP) 2025-007211

(51) Int. Cl. H10D 64/00; H10D 30/66

(52) U.S. Cl. CPC H10D 64/117; H10D 30/668; H10D 64/118

(57) ABSTRACT

According to an embodiment, a semiconductor device includes a first electrode, a second electrode, a semiconductor member, a third electrode, and a first insulating member. A first conductive portion faces a second partial region, a second semiconductor region, and a third semiconductor region in a second direction crossing a first direction. The first insulating member includes a first insulating portion and a second insulating portion. A first length of the first insulating portion along the second direction is shorter than a second length of the second insulating portion along the second direction.

### CROSS-REFERENCE TO RELATED APPLICATIONS

This application is based upon and claims the benefit of priority from Japanese Patent Application No.2025-007211, filed on January 17, 2025; the entire contents of which are incorporated herein by reference.

### FIELD

Embodiments of the invention relate to a semiconductor device.

### BACKGROUND

It is desirable to improve the breakdown voltage of semiconductor devices.

### BRIEF DESCRIPTION OF THE DRAWINGS

FIG. 1 is a schematic cross-sectional view of a semiconductor device according to an embodiment;

FIG. 2 is a graph illustrating characteristics of the semiconductor device according to the embodiment;

FIG. 3 is a graph illustrating characteristics of the semiconductor device according to the embodiment;

FIG. 4 is a graph illustrating characteristics of the semiconductor device according to the embodiment;

FIG. 5 is a schematic cross-sectional view of a semiconductor device according to the embodiment; and

FIG. 6 is a schematic cross-sectional view of a semiconductor device according to the embodiment.

### DETAILED DESCRIPTION

According to an embodiment of the invention, a semiconductor device includes a first electrode, a second electrode, a semiconductor member, a third electrode, and a first insulating member. The semiconductor member is provided between the first electrode and the second electrode in a first direction, the first direction extending from the first electrode toward the second electrode. The third electrode is provided between the first electrode and the second electrode. At least a part of the first insulating member is provided between the third electrode and the semiconductor member. The third electrode includes a first conductive portion and a second conductive portion. The second conductive portion is between the first electrode and the first conductive portion in the first direction. The semiconductor member includes a first semiconductor region of a first conductivity type, a second semiconductor region of a second conductivity type, and a third semiconductor region of the first conductivity type. The first semiconductor region includes a first partial region and a second partial region. The first partial region is between the first electrode and the second conductive portion in the first direction. At least a part of the second semiconductor region is between the second partial region and the third semiconductor region. The third semiconductor region is electrically connected to the second electrode. The first conductive portion faces the second partial region, the second semiconductor region, and the third semiconductor region in a second direction crossing the first direction. The first insulating member includes a first insulating portion between the first conductive member and the semiconductor member in the second direction, and a second insulating portion between the second conductive member and the semiconductor member in the second direction. A first length of the first insulating portion along the second direction is shorter than a second length of the second insulating portion along the second direction.

Hereinafter, embodiments of the invention will be described with reference to the drawings.

The drawings are schematic or conceptual, and the relationship between the thickness and width of each portion, the proportions of sizes among portions, and so on are not necessarily the same as the actual values. Even the dimensions and proportion of the same portion may be illustrated differently depending on the drawing.

In the specification and drawings, components similar to those described in regard to a drawing thereinabove are marked with like reference numerals, and a detailed description is omitted as appropriate.

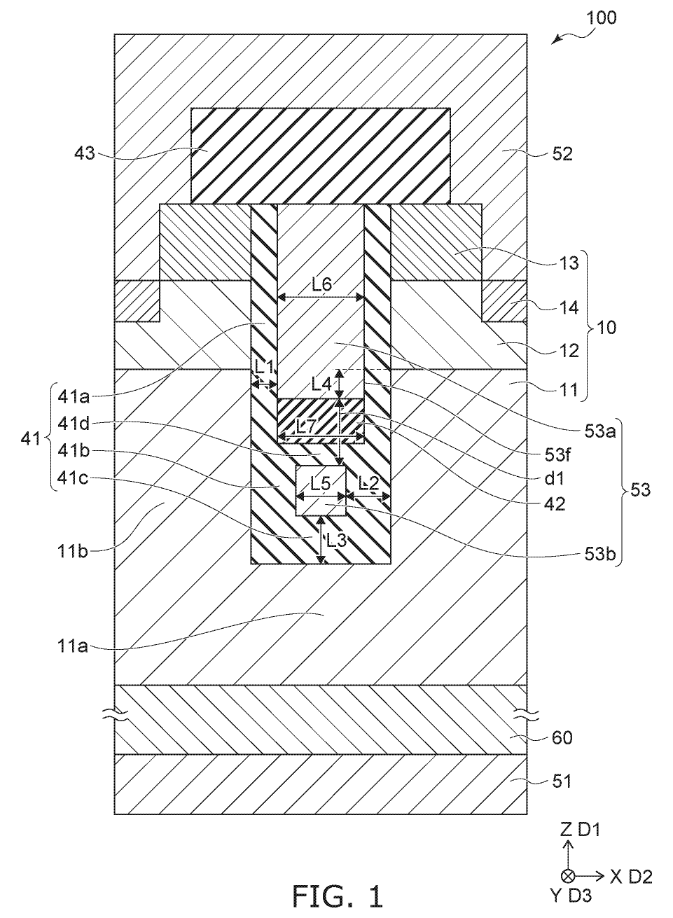

FIG. 1 is a schematic cross-sectional view of a semiconductor device according to an embodiment.

As shown in FIG. 1, a semiconductor device 100 according to the embodiment includes a first electrode 51, a second electrode 52, a semiconductor member 10, a third electrode 53, and a first insulating member 41.

The semiconductor member 10 is provided between the first electrode 51 and the second electrode 52 in a first direction D1 to the first electrode 51 and the second electrode 52.

The first direction D1 is taken as a Z-axis direction. One direction perpendicular to the Z-axis direction is taken as an X-axis direction. A direction perpendicular to the Z-axis direction and the X-axis direction is taken as a Y-axis direction. A second direction D2 is, for example, the X-axis direction.

The cross-sectional structure shown in FIG. 1 extends along the Y-axis direction.

The third electrode 53 is provided between the first electrode 51 and the second electrode 52. The third electrode 53 includes a first conductive portion 53a and a second conductive portion 53b.

At least a part of the first insulating member 41 is provided between the third electrode 53 and the semiconductor member 10. The first insulating member 41 insulates the third electrode 53 and the semiconductor member 10 from each other.

The second conductive portion 53b is between the first electrode 51 and the first conductive portion 53a in the first direction D1. The second conductive portion 53b is separated from the first conductive portion 53a.

The semiconductor member 10 includes a first semiconductor region 11 of a first conductivity type, a second semiconductor region 12 of a second conductivity type, and a third semiconductor region 13 of the first conductivity type. The first semiconductor region 11 includes a first partial region 11a and a second partial region 11b. The first partial region 11a is between the first electrode 51 and the second conductive portion 53b in the first direction D1. At least a part of the second semiconductor region 12 is between the second partial region 11b and the third semiconductor region 13. The third semiconductor region 13 is electrically connected to the second electrode 52. The first conductive portion 53a faces the second partial region 11b, the second semiconductor region 12, and the third semiconductor region 13 in the second direction D2 crossing the first direction D1.

For example, the first conductivity type is one of the n-type and the p-type. The second conductivity type is the other of the n-type and the p-type. In the embodiment, the first conductivity type may be the p-type, and the second conductivity type may be the n-type. It is assumed hereinafter that the first conductivity type is the n-type, and the second conductivity type is the p-type.

The first insulating member 41 includes a first insulating portion 41a and a second insulating portion 41b. The first insulating portion 41a is between the first conductive portion 53a and the semiconductor member 10 in the second direction D2. The second insulating portion 41b is between the second conductive portion 53b and the semiconductor member 10 in the second direction D2.

A first length L1 of the first insulating portion 41a in the second direction D2 is shorter than a second length L2 of the second insulating portion 41b in the second direction D2. The second length L2 is longer than the first length L1.

In the semiconductor device 100, the current flowing between the first electrode 51 and the second electrode 52 can be controlled by the potential of the third electrode 53. The potential of the third electrode 53 is, for example, a potential based on the potential of the first electrode 51. The first electrode 51 functions as, for example, one of the source electrode and the drain electrode. The second electrode 52 functions as, for example, the other of the source electrode and the drain electrode. The third electrode 53 functions as, for example, the gate electrode. The semiconductor device 100 is, for example, a metal-oxide-semiconductor field-effect transistor (MOSFET). For example, the first electrode 51 is the drain electrode. The second electrode 52 is the source electrode.

A reference example in which the second length L2 is the same as the first length L1 in the lower portion of the gate electrode is conceivable. In the reference example, electric field concentration occurs in the periphery of the lower portion of the gate electrode. This causes damage to the first insulating member 41 or a leakage current. In the semiconductor device 100 according to the embodiment, the first length L1 is shorter than the second length L2. The insulating portion in the lower portion of the gate electrode is thick. This reduces, for example, the electric field. For example, damage to the first insulating member 41 is suppressed. For example, the leakage current is suppressed. For example, the electric field applied to the periphery of the gate electrode when a high voltage is applied to the drain electrode can be reduced. According to the embodiment, the breakdown voltage can be improved.

The third electrode 53 may extend along a third direction D3. The third direction D3 crosses a plane that includes the first direction D1 and the second direction D2. The third direction D3 may be, for example, the Y-axis direction.

As shown in FIG. 1, the semiconductor device 100 according to the embodiment further includes a second insulating member 42.

The first insulating member 41 further includes a fourth insulating portion 41d between the second conductive portion 53b and the first conductive portion 53a in the first direction D1. The second conductive portion 53b is separated from the first conductive portion 53a in the first direction D1.

The distance between the second conductive portion 53b and the first conductive portion 53a along the first direction D1 is defined as a first distance d1. The first distance d1 is, for example, longer than the first length L1. The first distance d1 is, for example, longer than the second length L2.

The second insulating member 42 is between the fourth insulating portion 41d and the first conductive portion 53a in the first direction D1. The second insulating member 42 and the fourth insulating portion 41d insulate the first conductive portion 53a and the second conductive portion 53b from each other. The presence of the fourth insulating portion 41d between the second conductive portion 53b and the first conductive portion 53a and the presence of a third insulating portion 41c between the first partial region 11a and the second conductive portion 53b reduce, for example, local concentration of the electric field.

The semiconductor device 100 may include a substrate layer 60. The substrate layer 60 is between the first electrode 51 and the first semiconductor region 11 in the first direction D1.

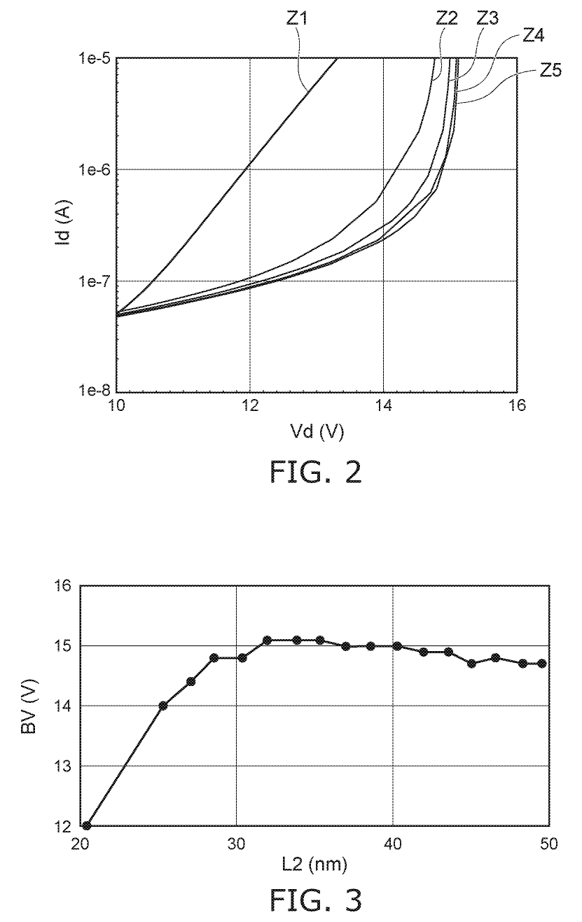

FIG. 2 is a graph illustrating characteristics of the semiconductor device according to the embodiment.

The horizontal axis in FIG. 2 represents the drain voltage. The vertical axis represents the drain current. In FIG. 2, the characteristic Z1 corresponds to the reference example. The characteristic Z2, the characteristic Z3, the characteristic Z4, and the characteristic Z5 correspond to the semiconductor device 100 according to the embodiment. In the characteristic Z2, the relative dielectric constant of the second insulating member 42 is 1.0. In the characteristic Z3, the relative dielectric constant of the second insulating member 42 is 3.9. In the characteristic Z4, the relative dielectric constant of the second insulating member 42 is 7.5. In the characteristic Z5, the relative dielectric constant of the second insulating member 42 is 10.0. The characteristic Z3 corresponds to a case where the second insulating member 42 is SiO₂. The characteristic Z4 corresponds to a case where the second insulating member 42 is SiN.

The characteristic Z2, the characteristic Z3, and the characteristic Z4 shift to the right (increases in the drain voltage) with reference to the characteristic Z1. In the characteristic Z2, the characteristic Z3, and the characteristic Z4, as the relative dielectric constant of the second insulating member 42 increases, the characteristics shift to the right. As the relative dielectric constant of the second insulating member 42 increases, the leakage current decreases and the breakdown voltage increases.

A second concentration of N (nitrogen) in the second insulating member 42 may be higher than a first concentration of N (nitrogen) in the fourth insulating portion 41d. Alternatively, the second insulating member 42 includes N, and the fourth insulating portion 41d does not include N.

The second concentration of N in the second insulating member 42 may be higher than the first concentration of N in the first insulating portion 41a, the second insulating portion 41b, and the third insulating portion 41c. The second insulating member 42 may include N, and the first insulating portion 41a, the second insulating portion 41b, and the third insulating portion 41c need not include N.

In the above, the second insulating member 42 and the fourth insulating portion 41d further include silicon.

In the embodiment, a second relative dielectric constant of the second insulating member 42 may be higher than a first relative dielectric constant of the fourth insulating portion 41d.

For example, the second insulating member 42 may be made of a material having a relative dielectric constant of a certain level or more. The relative dielectric constant of the second insulating member 42 may be, for example, 2.0 or more. For example, the second insulating member 42 may include at least one selected from the group consisting of SiO₂, AlN, HfO₂, and Al₂O₃.

The second insulating member 42 having a high relative dielectric constant is provided between the first conductive portion 53a and the second conductive portion 53b. The electric field applied to the periphery of the third electrode 53 can be reduced. The breakdown voltage is further improved.

The second conductive portion 53b of the third electrode 53 is electrically connected to the first conductive portion 53a.

As shown in FIG. 1, the first insulating member 41 further includes the third insulating portion 41c between the first partial region 11a and the second conductive portion 53b in the first direction D1.

The semiconductor member 10 further includes a fourth semiconductor region 14 of the second conductivity type. The fourth semiconductor region 14 is between the second semiconductor region 12 and the second electrode 52.

The semiconductor device 100 may further include a third insulating member 43. At least a part of the third insulating member 43 is between the third electrode 53 and the second electrode 52. The third insulating member 43 insulates the third electrode 53 and the second electrode 52 from each other.

FIG. 3 is a graph illustrating characteristics of the semiconductor device according to the embodiment.

The horizontal axis in FIG. 3 represents the second length L2. The vertical axis represents a voltage and indicates the breakdown voltage.

As shown in FIG. 3, the breakdown voltage increases when the second length L2 is in a range of 20 nm or more and less than 30 nm. When the second length L2 is 30 nm or more, the breakdown voltage is constant. In the embodiment, the second length L2 is preferably 30 nm or more. The second length L2 is preferably 30 nm or more and 40 nm or less.

The second length L2 may be at least 1.2 times the first length L1.

A third length L3 of the third insulating portion 41c along the first direction D1 may be longer than the first length L1.

As shown in FIG. 1, the first conductive portion 53a includes a facing region 53f facing the second partial region 11b in the second direction D2. The length of the facing region 53f along the first direction D1 is defined as a fourth length L4. Example characteristics when the fourth length L4 is changed will be described below.

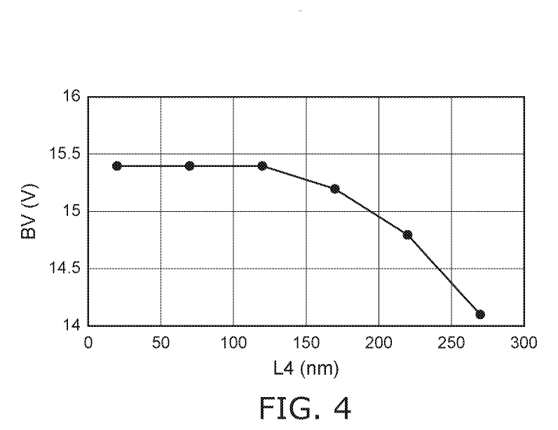

FIG. 4 is a graph illustrating characteristics of the semiconductor device according to the embodiment.

The horizontal axis in FIG. 4 represents the fourth length L4. The vertical axis represents the breakdown voltage BV. As shown in FIG. 4, when the fourth length L4 exceeds 150 nm, the breakdown voltage tends to decrease. The fourth length L4 is preferably 150 nm or less. The fourth length L4 is longer than 0.

As shown in FIG. 1, a sixth length L6 of the first conductive portion 53a in the second direction D2 may be longer than a fifth length L5 of the second conductive portion 53b in the second direction D2.

As shown in FIG. 1, the fifth length L5 of the second conductive portion 53b in the second direction D2 may be shorter than a seventh length L7 of the second insulating member 42 in the second direction D2.

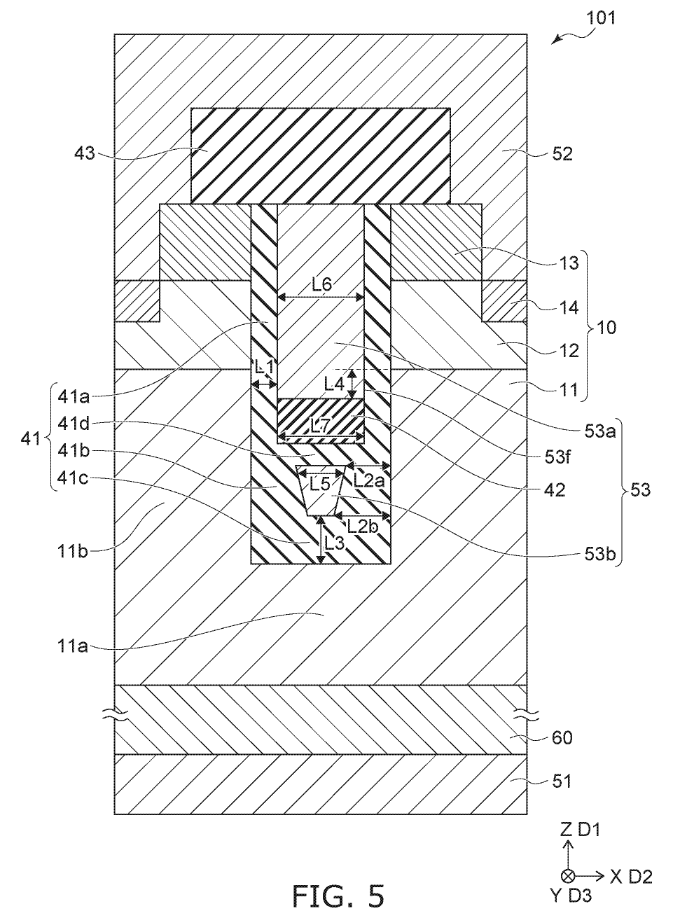

FIG. 5 is a schematic cross-sectional view of a semiconductor device according to the embodiment.

As shown in FIG. 5, in a semiconductor device 101 according to the embodiment, the configuration of the second conductive portion 53b is different from the configuration of the second conductive portion 53b in the semiconductor device 100. The configuration of the semiconductor device 101 may be otherwise similar to the configuration of the semiconductor device 100.

In the semiconductor device 101, the second length L2 decreases along the direction from the first electrode 51 to the second electrode 52. The second length L2 decreases from a length L2b to a length L2a along the direction from the first electrode 51 to the second electrode 52. The length (width) of the second conductive portion 53b in the second direction D2 may increase along the direction from the first electrode 51 to the second electrode 52.

In the semiconductor device 100 and the semiconductor device 101, the concentration of the impurity of the first conductivity type in the first semiconductor region 11 is lower than the concentration of the impurity of the first conductivity type in the third semiconductor region 13. The concentration of the impurity of the second conductivity type in the second semiconductor region 12 is lower than the concentration of the impurity of the second conductivity type in the fourth semiconductor region 14.

The carrier concentration of the first conductivity type in the first semiconductor region 11 is lower than the carrier concentration of the first conductivity type in the third semiconductor region 13. The carrier concentration of the second conductivity type in the second semiconductor region 12 is lower than the carrier concentration of the second conductivity type in the fourth semiconductor region 14. The first semiconductor region 11 is, for example, an n⁻-layer or an n-layer. The third semiconductor region 13 is, for example, an n⁺-layer. The second semiconductor region 12 is, for example, a p⁻-layer or a p-layer. The fourth semiconductor region 14 is, for example, a p⁺-layer.

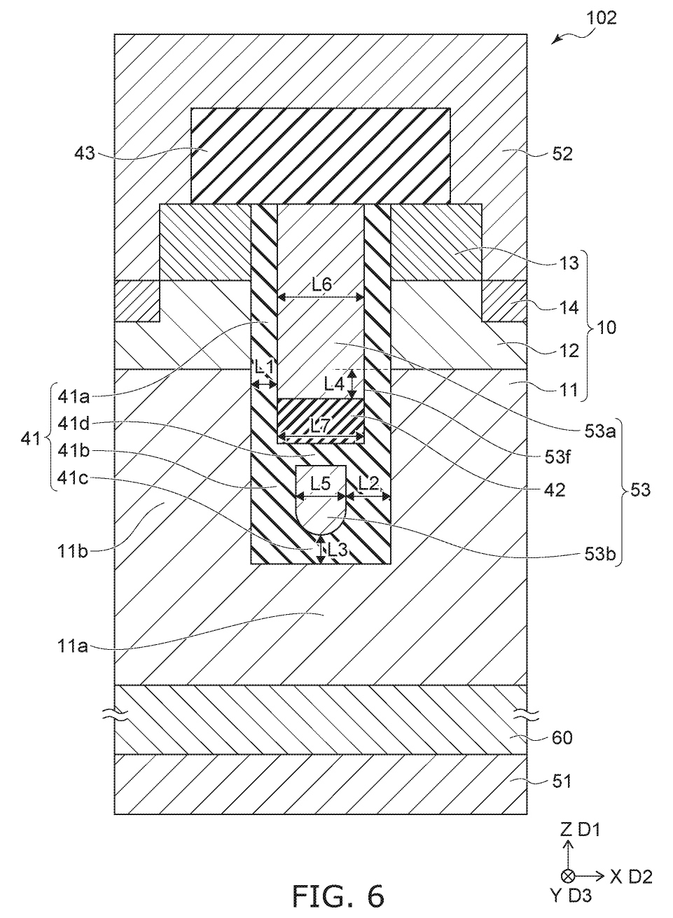

FIG. 6 is a schematic cross-sectional view of a semiconductor device according to the embodiment.

As shown in FIG. 6, in a semiconductor device 102 according to the embodiment, the configuration of the second conductive portion 53b is different from the configuration of the second conductive portion 53b in the semiconductor device 100. The configuration of the semiconductor device 102 may be otherwise similar to the configuration of the semiconductor device 100.

In the semiconductor device 102, the second length L2 decreases from the middle along the direction from the first electrode 51 to the second electrode 52. The length (width) of the second conductive portion 53b in the second direction D2 may increase along the direction from the first electrode 51 to the second electrode 52.

According to the embodiment, a semiconductor device whose breakdown voltage can be improved can be provided.

Certain embodiments of the invention have been described above with reference to specific examples. However, the invention is not limited to these specific examples. For example, those skilled in the art may similarly practice the invention by selecting, as appropriate, specific configurations of components, such as semiconductor members, electrodes, conductive portions, and insulating portions, included in the semiconductor devices from known art. Such practice is included in the scope of the invention to the extent that similar effects are attained.

Any two or more components in the specific examples may be combined within the extent of technical feasibility and are included in the scope of the invention to the extent that the spirit of the invention is included.

Moreover, all semiconductor devices practicable by design modification made as appropriate by those skilled in the art based on the semiconductor devices described above as embodiments of the invention are also within the scope of the invention to the extent that the gist of the invention is included.

Moreover, various variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first electrode;
a second electrode;
a semiconductor member provided between the first electrode and the second electrode in a first direction, the first direction extending from the first electrode toward the second electrode;
a third electrode provided between the first electrode and the second electrode; and
a first insulating member, at least a part of the first insulating member being provided between the third electrode and the semiconductor member,
the third electrode including a first conductive portion and a second conductive portion,
the second conductive portion being between the first electrode and the first conductive portion in the first direction,
the semiconductor member including
a first semiconductor region of a first conductivity type,
a second semiconductor region of a second conductivity type, and
a third semiconductor region of the first conductivity type,
the first semiconductor region including a first partial region and a second partial region,
the first partial region being between the first electrode and the second conductive portion in the first direction,
at least a part of the second semiconductor region being between the second partial region and the third semiconductor region,
the third semiconductor region being electrically connected to the second electrode,
the first conductive portion facing the second partial region, the second semiconductor region, and the third semiconductor region in a second direction crossing the first direction,
the first insulating member including
a first insulating portion between the first conductive portion and the semiconductor member in the second direction, and
a second insulating portion between the second conductive portion and the semiconductor member in the second direction,
a first length of the first insulating portion along the second direction being shorter than a second length of the second insulating portion along the second direction.

2. The semiconductor device according to claim 1, further comprising:
a second insulating member,
the first insulating member further including a fourth insulating portion between the second conductive portion and the first conductive portion in the first direction,
the second insulating member being between the fourth insulating portion and the first conductive portion in the first direction,
at least one of the following being satisfied:
(i) a second concentration of N in the second insulating member being higher than a first concentration of N in the fourth insulating portion, or
(ii) the second insulating member including N and the fourth insulating portion not including N.

3. The semiconductor device according to claim 2, wherein the second insulating member and the fourth insulating portion include silicon.

4. The semiconductor device according to claim 1, further comprising:
a second insulating member,
the first insulating member further including a fourth insulating portion between the second conductive portion and the first conductive portion in the first direction,
the second insulating member being between the fourth insulating portion and the first conductive portion in the first direction,
a second relative dielectric constant of the second insulating member being higher than a first relative dielectric constant of the fourth insulating portion.

5. The semiconductor device according to claim 2, wherein the second insulating member includes at least one selected from the group consisting of SiO₂ AlN, HfO₂ and Al₂O₃.

6. The semiconductor device according to claim 1, wherein the second conductive portion is electrically connected to the first conductive portion.

7. The semiconductor device according to claim 1, wherein the second conductive portion is separated from the first conductive portion.

8. The semiconductor device according to claim 1, wherein
the first insulating member further includes a third insulating portion between the first partial region and the second conductive portion in the first direction, and
a third length of the third insulating portion along the first direction is longer than the first length.

9. The semiconductor device according to claim 1, wherein
the semiconductor member further includes a fourth semiconductor region of the second conductivity type, and
the fourth semiconductor region is between the second semiconductor region and the second electrode.

10. The semiconductor device according to claim 1, further comprising:
a third insulating member,
at least a part of the third insulating member being between the third electrode and the second electrode.

11. The semiconductor device according to claim 1, wherein
the first conductive portion includes a facing region facing the second partial region in the second direction, and
a fourth length of the facing region along the first direction is longer than 0 nm and 150 nm or less.

12. The semiconductor device according to claim 1, wherein the second length is at least 1.2 times the first length.

13. The semiconductor device according to claim 1, wherein the second length is 30 nm or more.

14. The semiconductor device according to claim 1, wherein a sixth length of the first conductive portion in the second direction is longer than a fifth length of the second conductive portion in the second direction.

15. The semiconductor device according to claim 2, wherein a fifth length of the second conductive portion in the second direction is shorter than a seventh length of the second insulating member in the second direction.

16. The semiconductor device according to claim 1, wherein the second length decreases along the first direction.

17. The semiconductor device according to claim 1, wherein a first distance between the second conductive portion and the first conductive portion along the first direction is longer than the first length.

18. The semiconductor device according to claim 1, wherein a first distance between the second conductive portion and the first conductive portion along the first direction is longer than the second length.

19. The semiconductor device according to claim 1, wherein a concentration of an impurity of the first conductivity type in the first semiconductor region is lower than a concentration of an impurity of the first conductivity type in the third semiconductor region.

20. The semiconductor device according to claim 9, wherein a concentration of an impurity of the second conductivity type in the second semiconductor region is lower than a concentration of an impurity of the second conductivity type in the fourth semiconductor region.
